(19) United States
(12) Patent Application Publication
(10) Pub. No.: US 2025/0380397 A1
(43) Pub. Date: Dec. 11, 2025

(54) SEMICONDUCTOR STRUCTURE AND FORMING METHOD THEREFOR

(71) Applicant: CXMT Corporation, Hefei City (CN)

(72) Inventor: Xiaojie LI, Hefei City (CN)

(73) Assignee: CXMT Corporation, Hefei City (CN)

(21) Appl. No.: 18/943,604

(22) Filed: Nov. 11, 2024

Related U.S. Application Data
(63) Continuation of application No. PCT/CN2024/118033, filed on Sep. 10, 2024.

(30) Foreign Application Priority Data
Jun. 7, 2024 (CN) 202410740575.0

(51) Int. Cl. H10B 12/00

(52) U.S. Cl. CPC H10B 12/05; H10B 12/30

(57) ABSTRACT

The method includes: providing a substrate, forming a plurality of first grooves in a first region of the substrate, and forming a first dielectric layer on side walls of the plurality of first grooves; etching the substrate along bottoms of the plurality of first grooves to form a second groove positioned inside the substrate, and filling a second dielectric layer within the second groove; forming a third groove in a second region of the substrate, and forming a third dielectric layer on side walls of the third groove; etching the substrate along a bottom of the third groove to form a fourth groove positioned inside the substrate, the fourth groove exposing a side surface of the second dielectric layer along a first direction; filling a fourth dielectric layer within the fourth groove; and interconnecting the fourth dielectric layer positioned inside the substrate to the second dielectric layer inside the substrate.

### CROSS-REFERENCE TO RELATED APPLICATIONS

This application is a continuation of PCT/CN2024/118033, filed on Sep. 10, 2024, which claims priority to Chinese Patent Application No. 202410740575.0 filed on Jun. 7, 2024. The disclosures of the above-referenced applications are hereby incorporated by reference in their entirety.

### BACKGROUND

As the integration density of dynamic memories becomes increasingly higher, higher requirements are placed on the arrangement mode and size of transistors in the array structure of the dynamic memories. However, due to the limitations of manufacturing factors such as lithography machines and various electrical parasitic effects, there is a limit to the reduction of the critical size of the transistor. Therefore, how to make a chip with higher storage density on one wafer is a research direction of many scientific researchers and semiconductor practitioners.

The advent of three-dimensional dynamic random access memory (3D DRAM), particularly 3D DRAM including a multilayer horizontal cell (MHC), typically including a plurality of transistors stacked on a substrate, meets the above requirement. To form a stacked MHC, an initial stack structure needs to be formed on the substrate, and then processes such as etching, ion implantation, and deposition are performed on the stack structure. Therefore, in the processes, the substrate is easily etched or ion-implanted, resulting in stripping of the stack structure from the substrate or substrate leakage, which affects the electrical performance of the finally formed memory cell.

### SUMMARY

Embodiments of the present disclosure relate to the technical field of semiconductors, in particular to a method for manufacturing a semiconductor structure and a semiconductor structure thereof.

Embodiments of the present disclosure provide a method for manufacturing a semiconductor structure and a semiconductor structure thereof, which at least facilitate the prevention of etching of a substrate, help to reduce the risk of stripping of a stack structure from the substrate, reduce the leakage of a memory cell, and enhance the overall electrical performance of the memory cell.

An aspect of the embodiments of the present disclosure provides a method for manufacturing a semiconductor structure. The method includes:
providing a substrate, the substrate including a first region and a second region distributed along a first direction, and a stack structure being formed on the substrate;
forming a plurality of first grooves, the plurality of first grooves being positioned in the first region of the substrate and being positioned in the substrate, the plurality of first grooves extending along the first direction, the plurality of first grooves being spaced apart along a second direction, and a plane determined by the first direction and the second direction being parallel to a surface of the substrate;
forming a first dielectric layer on side walls of the plurality of first grooves;
etching the substrate along bottoms of the plurality of first grooves to form a second groove positioned inside the substrate, such that along the second direction, two of the plurality of first grooves adjacent to each other communicate with each other through the second groove; and
filling a second dielectric layer within the second groove.

In some embodiments, the method further includes:
forming a third groove, the third groove being positioned in the second region of the substrate and extending along the second direction, and the third groove being positioned in the substrate;
forming a third dielectric layer on side walls of the third groove;
etching the substrate along a bottom of the third groove to form a fourth groove positioned inside the substrate, the fourth groove exposing a side surface of the second dielectric layer along the first direction;
filling a fourth dielectric layer within the fourth groove; and
interconnecting the fourth dielectric layer positioned inside the substrate to the second dielectric layer positioned inside the substrate.

In some embodiments, the method further includes: before forming the plurality of first grooves, patterning the stack structure to form an initial laminated structure including a plurality of first portions positioned in the first region and a second portion positioned in the second region, where the plurality of first portions extend along the first direction and the second portion extends along the second direction;
the plurality of first portions are spaced apart along the second direction, and a first trench isolation structure is formed between two of the plurality of first portions adjacent to each other;
the substrate at bottoms of the first trench isolation structures is etched to form the plurality of first grooves; and
the plurality of first grooves communicate with the first trench isolation structures.

In some embodiments, the method further includes: before forming the third groove, patterning the second portion of the second region to form a second trench isolation structure, where the second trench isolation structure extends along the second direction, and the substrate at a bottom of the second trench isolation structure is etched to form the third groove;
the third groove communicates with the second trench isolation structure.

In some embodiments, the second groove isolates the substrate positioned in the first region into a first substrate below the second groove and a second substrate above the second groove, the fourth groove isolates the substrate positioned in the second region into a third substrate below the fourth groove and a fourth substrate above the fourth groove, the first substrate is interconnected to the third substrate, and the second substrate is interconnected to the fourth substrate.

In some embodiments, the method further includes: filling a first sacrificial dielectric layer within the first trench isolation structures, and filling a second sacrificial dielectric layer within the second trench isolation structure, the first sacrificial dielectric layer and/or the second sacrificial dielectric layer being made of polycrystalline silicon or a low-k dielectric material.

In some embodiments, the first sacrificial dielectric layer and/or the second sacrificial dielectric layer are/is in contact with the substrate, or the second dielectric layer or the fourth dielectric layer is provided between the first sacrificial dielectric layer and/or the second sacrificial dielectric layer and the substrate.

In some embodiments, the stack structure includes first semiconductor layers and second semiconductor layers stacked sequentially, the first semiconductor layers are made of silicon germanium, and the second semiconductor layers are made of silicon.

In some embodiments, the first dielectric layer, the second dielectric layer, the third dielectric layer, or the fourth dielectric layer is made of one or more of silicon oxide, silicon nitride, silicon oxynitride, and a low-k dielectric material.

In some embodiments, along a third direction, a depth of the fourth groove is greater than or equal to a depth of the second groove, and the third direction intersects with the plane determined by the first direction and the second direction.

In some embodiments, along the third direction, a thickness of the fourth dielectric layer is greater than a thickness of the second dielectric layer.

Another aspect of the embodiments of the present disclosure further provides a semiconductor structure. The semiconductor structure includes:
a substrate, including a first region and a second region distributed along a first direction;
a stack device layer, positioned on an upper surface of the substrate,
where the substrate includes a first substrate and a second substrate positioned in the first region, and a third substrate and a fourth substrate positioned in the second region; the first substrate and the second substrate are spaced apart along a third direction, and the third substrate and the fourth substrate are spaced apart along the third direction; the first direction is parallel to a surface of the substrate, and the third direction intersects with the surface of the substrate;
a second dielectric layer, positioned between the first substrate and the second substrate; and
a fourth dielectric layer, positioned between the third substrate and the fourth substrate,
where the second dielectric layer is interconnected to the fourth dielectric layer; and
along the third direction, a thickness of the fourth dielectric layer is greater than a thickness of the second dielectric layer.

In some embodiments, along the first direction, an interface between the fourth dielectric layer and the third substrate and/or the fourth substrate is in a shape of a curved surface.

In some embodiments, along a second direction, an interface between the second dielectric layer and the first substrate and/or the second substrate is in a shape of a curved surface, and a plane determined by the first direction and the second direction is parallel to the surface of the substrate.

In some embodiments, the stack device layer includes a plurality of transistor structures and/or a plurality of capacitor structures laminated along the third direction.

The technical solutions provided in the embodiments of the present disclosure have at least the following advantages. A substrate is provided, a plurality of first grooves are formed in a first region of the substrate, a first dielectric layer is formed on the side walls of the plurality of first grooves, the substrate is etched along the bottoms of the plurality of first grooves to form a second groove positioned inside the substrate, and a second dielectric layer is filled within the second groove; a third groove is formed in a second region of the substrate, and a third dielectric layer is formed on the side walls of the third groove; the substrate is etched along the bottom of the third groove to form a fourth groove positioned inside the substrate, the fourth groove exposing the side surface of the second dielectric layer along a first direction; a fourth dielectric layer is filled within the fourth groove; the fourth dielectric layer positioned inside the substrate is interconnected to the second dielectric layer inside the substrate. The dielectric layers formed in the embodiments of the present disclosure can protect the substrate, prevent the stripping of the stack structure and substrate leakage, and improve the electrical performance of the stack device.

### BRIEF DESCRIPTION OF THE DRAWINGS

One or more embodiments are exemplarily illustrated with reference to pictures in the corresponding drawings, and these exemplary illustrations are not to be construed as limiting the embodiments. Unless expressly stated otherwise, the pictures in the drawings do not constitute a proportion limitation. To more clearly illustrate the technical solutions in the embodiments of the present disclosure or the conventional technology, a brief introduction to the drawings required to be used in the embodiments is given hereinafter. It is evident that the drawings described hereinafter are merely some embodiments of the present disclosure. For those of ordinary skill in the art, other drawings may be further obtained based on these drawings without creative effort.

FIG. 1 is a flowchart of a method for manufacturing a semiconductor structure according to an embodiment of the present disclosure.

FIG. 2 is a first cross-sectional view corresponding to steps of a method for manufacturing a semiconductor structure according to an embodiment of the present disclosure.

FIG. 3 is a second cross-sectional view corresponding to steps of a method for manufacturing a semiconductor structure according to an embodiment of the present disclosure.

FIG. 4A and FIG. 4B are third cross-sectional views along lines A-A′ and B-B′, respectively, corresponding to steps of a method for manufacturing a semiconductor structure according to an embodiment of the present disclosure.

FIG. 5A and FIG. 5B are fourth cross-sectional views along lines A-A′ and B-B′, respectively, corresponding to steps of a method for manufacturing a semiconductor structure according to an embodiment of the present disclosure.

FIG. 6A and FIG. 6B are fifth cross-sectional views along lines A-A′ and B-B′, respectively, corresponding to steps of a method for manufacturing a semiconductor structure according to an embodiment of the present disclosure.

FIG. 7A and FIG. 7B are sixth cross-sectional views along lines A-A′ and B-B′, respectively, corresponding to steps of a method for manufacturing a semiconductor structure according to an embodiment of the present disclosure.

FIG. 8A and FIG. 8B are seventh cross-sectional views along lines A-A′ and B-B′, respectively, corresponding to steps of a method for manufacturing a semiconductor structure according to an embodiment of the present disclosure.

FIG. 9A and FIG. 9B are eighth cross-sectional views along lines A-A′ and B-B′, respectively, corresponding to steps of a method for manufacturing a semiconductor structure according to an embodiment of the present disclosure.

FIG. 10A and FIG. 10B are nineth cross-sectional views along lines A-A′ and B-B′, respectively, corresponding to steps of a method for manufacturing a semiconductor structure according to an embodiment of the present disclosure.

FIG. 11A and FIG. 11B are tenth cross-sectional views along lines A-A′ and B-B′, respectively, corresponding to steps of a method for manufacturing a semiconductor structure according to an embodiment of the present disclosure.

FIG. 12 is an eleventh cross-sectional view corresponding to steps of a method for manufacturing a semiconductor structure according to an embodiment of the present disclosure.

FIG. 13 is a twelfth cross-sectional view corresponding to steps of a method for manufacturing a semiconductor structure according to an embodiment of the present disclosure.

FIG. 14 is a thirteenth cross-sectional view corresponding to steps of a method for manufacturing a semiconductor structure according to an embodiment of the present disclosure.

FIG. 15 is a fourteenth cross-sectional view corresponding to steps of a method for manufacturing a semiconductor structure according to an embodiment of the present disclosure.

FIG. 16 is a fifteenth cross-sectional view corresponding to steps of a method for manufacturing a semiconductor structure according to an embodiment of the present disclosure.

FIG. 17 is a sixteenth cross-sectional view corresponding to steps of a method for manufacturing a semiconductor structure according to an embodiment of the present disclosure.

FIG. 18 is a seventeenth cross-sectional view corresponding to steps of a method for manufacturing a semiconductor structure according to an embodiment of the present disclosure.

FIG. 19 is an eighteenth cross-sectional view corresponding to steps of a method for manufacturing a semiconductor structure according to an embodiment of the present disclosure.

FIG. 20 is a nineteenth cross-sectional view corresponding to steps of a method for manufacturing a semiconductor structure according to an embodiment of the present disclosure.

FIG. 21 is a first schematic view of partial cross-section of a semiconductor structure according to an embodiment of the present disclosure.

FIG. 22 is a second schematic view of partial cross-section of a semiconductor structure according to an embodiment of the present disclosure.

FIG. 23 is a third schematic view of partial cross-section of a semiconductor structure according to an embodiment of the present disclosure.

Reference numerals in the figures are as follows:
I: first region; II: second region; 201: substrate; 2011: first substrate; 2012: second substrate; 2013: third substrate; 2014: fourth substrate; 200: stack structure; 202: first semiconductor layer; 203: second semiconductor layer; 300: initial laminated structure; 301: first portion; 302: second portion; 204: first trench isolation structure; 208: second trench isolation structure; 206: first gap; 210: second gap; 205: first groove; 207: second groove; 209: third groove; 211: fourth groove; 400: stack device layer; 401: first dielectric layer; 501: second dielectric layer; 601: first sacrificial dielectric layer; 701: third dielectric layer; 801: fourth dielectric layer; 901: second sacrificial dielectric layer.

### DETAILED DESCRIPTION

The technical solutions of the present disclosure will be further elaborated below with reference to the drawings and embodiments. While exemplary implementations of the present disclosure are shown in the drawings, it should be understood that the present disclosure may be implemented in various forms and should not be limited by the embodiments set forth herein. Rather, these embodiments are provided so that the present disclosure will be more thoroughly understood and the scope of the present disclosure will be fully conveyed to those skilled in the art.

The present disclosure is more specifically described in the following paragraphs with reference to the drawings by way of example. Advantages and features of the present disclosure will become apparent from the following description and claims. It should be noted that the drawings are all in a very simplified form and not to precise scale, and are provided only for the purpose of facilitating a convenient and clear description of the embodiments of the present disclosure.

It will be understood that the meaning of “on”, “above”, and “over” in the present disclosure should be interpreted in the broadest manner such that “on” not only includes the meaning of “on” something with no intermediate feature or layer therebetween (i.e., directly on something) but also includes the meaning of “on” something with an intermediate feature or a layer therebetween.

In the embodiments of the present disclosure, the terms “first”, “second”, “third”, and the like are used for distinguishing similar objects and are not necessarily used for describing a particular order or sequence.

In the embodiments of the present disclosure, the term “layer” refers to a material portion that includes a region having a thickness. A layer may extend over the entirety of the underlying or overlying structure or may have an extent that is less than the extent of the underlying or overlying structure. Furthermore, a layer may be a region of a homogeneous or inhomogeneous continuous structure having a thickness less than the thickness of a continuous structure. For example, a layer may be positioned between a top surface and a bottom surface of a continuous structure, or a layer may be positioned between any pair of horizontal planes at the top surface and the bottom surface of the continuous structure. A layer may extend horizontally, vertically, and/or along inclined surfaces. A layer may include a plurality of sub-layers.

It should be noted that unless conflicting, the technical solutions described in the embodiments of the present disclosure may be arbitrarily combined.

It can be seen from the background section that, in the process of manufacturing the 3D DRAM, a stack structure positioned on a substrate usually needs to be formed first, and structures such as transistors, bit lines, word lines, and capacitors of the memory cell are formed by processes such as etching or ion implantation of the stack structure, and the number of the stack structures directly determines the storage density of the memory cell. Therefore, the formation process of the stack structure is critical to the final performance and storage density of the 3D DRAM. The current stack structures are generally divided into two types; one is the non-epitaxial structure (non-EPI) stack of a dielectric layer and a dielectric layer (ONON) or a dielectric layer and a semiconductor layer (OPOP) formed through a deposition process, and the other is the epitaxial structure (EPI) of a semiconductor stack (generally Si-SiGe) formed through an epitaxial process. Since the stack structure formed by the epitaxial structure is generally consistent with the lattice structure of the substrate, the formed stack structure has better lattice consistency, and the electrical properties of the formed memory cells tend to be consistent. Therefore, the stack structure formed based on the EPI process is the main process method for forming the 3D DRAM at present. The EPI process requires the substrate to serve as an epitaxial substrate for the epitaxial process, and thus an etching stop layer cannot be formed on the surface of the substrate. During the etching process, due to the limitation of the etching selectivity, the substrate for forming the stack structure is also etched, such that the substrate cannot be effectively protected and is prone to multiple times of etching or ion implantation, resulting in the risk of stripping of the stack structure on the substrate. In addition, due to the ion implantation of the substrate, there is a possibility of leakage on the substrate, which may even cause abnormal operation of the memory cell, such that the electrical performance of the memory cell is reduced, and the device yield of the finally formed 3D DRAM is affected.

An embodiment of the present disclosure provides a method for manufacturing a semiconductor structure. The method includes: providing a substrate, forming a plurality of first grooves in a first region of the substrate, and forming a first dielectric layer on the side walls of the plurality of first grooves; etching the substrate along the bottoms of the plurality of first grooves to form a second groove positioned inside the substrate, and filling a second dielectric layer within the second groove; forming a third groove in a second region of the substrate, and forming a third dielectric layer on the side walls of the third groove; etching the substrate along the bottom of the third groove to form a fourth groove positioned inside the substrate, the fourth groove exposing the side surface of the second dielectric layer along a first direction; filling a fourth dielectric layer within the fourth groove; and interconnecting the fourth dielectric layer positioned inside the substrate to the second dielectric layer inside the substrate. The dielectric layers formed in the embodiments of the present disclosure can protect the substrate, prevent the stripping of the stack structure and substrate leakage, and improve the electrical performance of the stack device. The embodiments of the present disclosure will be described in detail below with reference to the drawings. However, those of ordinary skill in the art can understand that in the embodiments of the present disclosure, numerous technical details are set forth in order to enable readers to better understand the embodiments of the present disclosure. However, the technical solutions claimed by the embodiments of the present disclosure can also be implemented even without these technical details and the various changes and modifications based on the following embodiments.

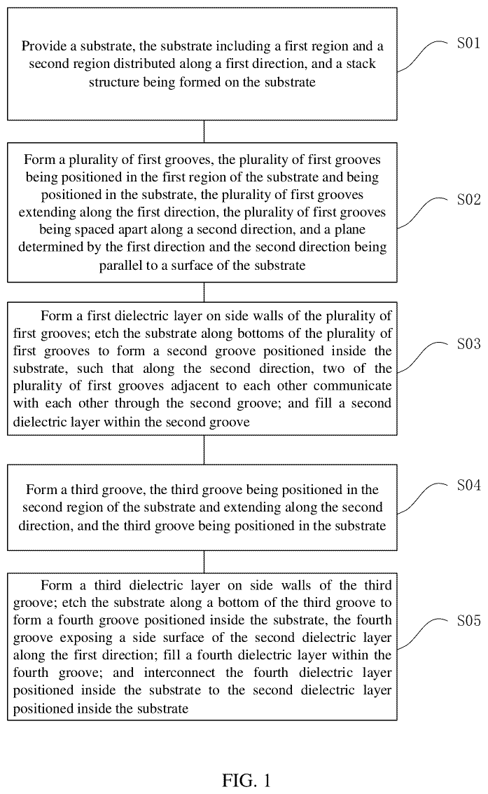

An embodiment of the present disclosure provides a method for manufacturing a semiconductor structure. The method for manufacturing a semiconductor structure provided in the embodiment of the present disclosure is described in detail below with reference to the drawings. FIG. 1 is a flowchart of a method for manufacturing a semiconductor structure according to an embodiment of the present disclosure.

Referring to FIG. 1, the method for manufacturing a semiconductor structure specifically includes the following steps.

In S01, a substrate is provided; the substrate includes a first region and a second region distributed along a first direction, and a stack structure is formed on the substrate.

In S02, a plurality of first grooves are formed, where the plurality of first grooves are positioned in the first region of the substrate and are positioned in the substrate, the plurality of first grooves extend along the first direction, the plurality of first grooves are spaced apart along a second direction, and a plane determined by the first direction and the second direction is parallel to the surface of the substrate.

In S03, a first dielectric layer is formed on the side walls of the plurality of first grooves; the substrate is etched along the bottoms of the plurality of first grooves to form a second groove positioned inside the substrate, such that along the second direction, two of the plurality of first grooves adjacent to each other communicate with each other through the second groove, and a second dielectric layer is filled within the second groove.

In S04, a third groove is formed; the third groove is positioned in the second region of the substrate and extends along the second direction, and the third groove is positioned in the substrate.

In S05, a third dielectric layer is formed on the side walls of the third groove; the substrate is etched along the bottom of the third groove to form a fourth groove positioned inside the substrate, the fourth groove exposing the side surface of the second dielectric layer along the first direction; a fourth dielectric layer is filled within the fourth groove; the fourth dielectric layer positioned inside the substrate is interconnected to the second dielectric layer positioned inside the substrate.

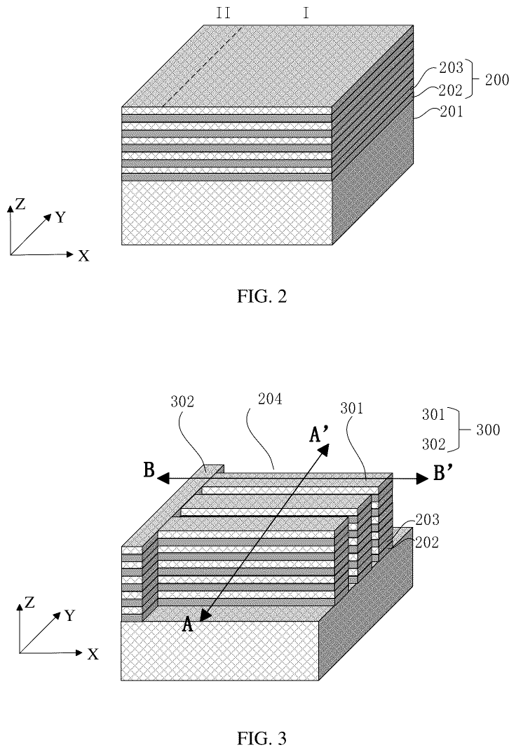

FIGS. 2 to 20 are partial schematic views corresponding to steps of a method for manufacturing a semiconductor structure according to an embodiment of the present disclosure. The method for manufacturing a semiconductor structure provided in the embodiment of the present disclosure is described in detail below with reference to FIGS. 2 to 20.

In step S01, a substrate is provided; the substrate includes a first region and a second region distributed along a first direction X, and a stack structure is formed on the substrate. Specifically, the following steps are included. As shown in FIG. 2, a substrate 201 is provided, and as shown by a dotted line in the figure, the substrate 201 includes a first region I and a second region II distributed along the first direction X, where the material of the substrate includes monocrystalline silicon, polycrystalline silicon, amorphous silicon, germanium, silicon carbide, silicon germanium, germanium on insulator (GOI), or silicon on insulator (SOI). In the embodiments of the present disclosure, in order to form a silicon-silicon germanium stack structure on the substrate by using an epitaxial process, the material of the substrate is selected to be a monocrystalline silicon material. In some embodiments, the N-type or P-type substrate 201 may be formed by performing N-type or P-type doping treatment and annealing treatment on the monocrystalline silicon material, and the N-type element may be a group V element such as a phosphorus (P) element, a bismuth (Bi) element, a stibium (Sb) element, or an arsenic (As) element. The P-type element may be a group III element such as a boron (B) element, an aluminum (Al) element, a gallium (Ga) element, or an indium (In) element. In some embodiments, the doping treatment may be performed only on the upper surface of the substrate to form an N-type doped layer or a P-type doped layer on the surface of the substrate, or the doping treatment may be performed on the entire substrate to form the N-type substrate 201 or the P-type substrate 201. In the embodiments of the present disclosure, before the stack structure is epitaxially formed on the substrate 201, the surface of the substrate 201 may be pretreated to remove impurities or a native oxide layer on the surface. As shown in FIG. 2, a multilayer stack structure 200 stacked along a third direction Z is formed on the substrate 201, and along the third direction, the stack structure 200 includes first semiconductor layers 202 and second semiconductor layers 203 stacked sequentially. The first semiconductor layers 202 may be formed of or include at least one of, for example, silicon germanium, silicon oxide, silicon nitride, and silicon oxynitride. In some embodiments, the first semiconductor layers 202 may be formed by an epitaxial growth method and may be, for example, silicon germanium layers. The second semiconductor layers 203 may be formed of or include at least one of, for example, silicon, germanium, silicon germanium, and indium gallium zinc oxide (IGZO). In some embodiments, the second semiconductor layers 203 may be formed of or include the same semiconductor material as the substrate 201. For example, the second semiconductor layers 203 may be formed by an epitaxial growth method and may be monocrystalline silicon layers. In the embodiments of the present disclosure, the epitaxially grown silicon germanium layer and silicon layer are taken as an example for illustration. The formed stack structure has a crystal structure similar to a superlattice, and since the lattice structures of the silicon germanium layer and the silicon layer are the same, the stack structure can be formed through epitaxial growth, which reduces the generation of defects in the stack structure, and is beneficial to improving the electrical performance of the formed semiconductor structure. The embodiments of the present disclosure take the formation of a five-layer stack structure as an example for illustration, but are not limited thereto in the actual process, and the specific number of stack layers can be selected based on the actual stacking requirement.

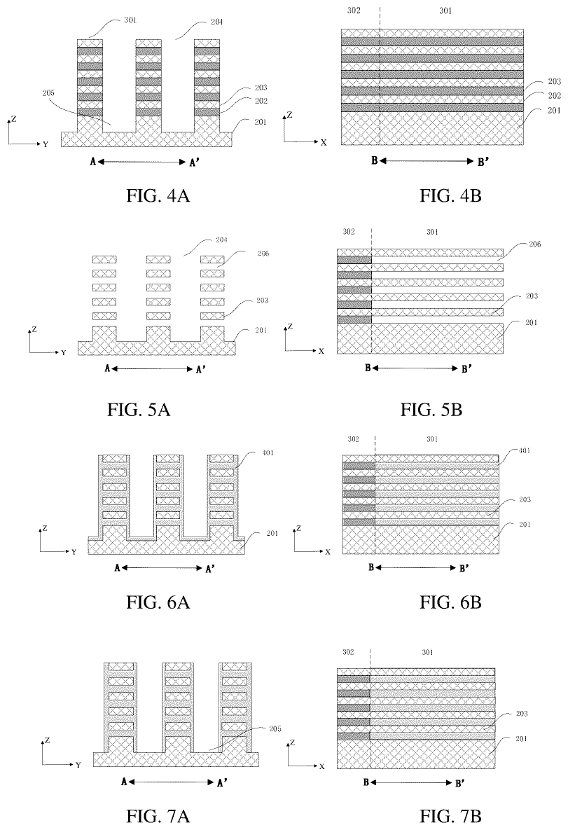

In step S02, a plurality of first grooves are formed, where the plurality of first grooves are positioned in the first region of the substrate and are positioned in the substrate, the plurality of first grooves extend along the first direction, the plurality of first grooves are spaced apart along a second direction, and a plane determined by the first direction and the second direction is parallel to the surface of the substrate. Specifically, the following steps are included. As shown in FIG. 3, a mask layer (not shown) is formed above the stack structure 200, and the stack structure 200 is patterned, where the patterning treatment includes dry etching, wet etching, or a combination of both. The patterned stack structure 200 forms an initial laminated structure 300, and the initial laminated structure 300 includes a plurality of first portions 301 positioned in the first region I and a second portion 302 positioned in the second region II; the plurality of first portions 301 extend along the first direction X, and the second portion 302 extends along the second direction Y; the plurality of first portions are spaced apart along the second direction, and a first trench isolation structure 204 is formed between two of the plurality of first portions adjacent to each other along the second direction; the first trench isolation structures 204 expose portions of the surface of the substrate 201. Through the exposed portions of the surface, the substrate 201 is subjected to dry or wet etching to form the plurality of first grooves 205 positioned in the first region I of the substrate. FIGS. 4A and 4B are cross-sectional views along lines A-A′ and B-B′ in FIG. 3 after etching the substrate 201, respectively. Referring to FIG. 3 and FIGS. 4A and 4B, the mask layer (not shown) is formed on the initial laminated structure 300, and the substrate 201 exposed by the first trench isolation structures 204 is etched to form the plurality of first grooves 205 extending along the third direction Z towards the inside of the substrate 201, the plurality of first grooves 205 extend along the first direction, and the plurality of first grooves 205 are spaced apart along the second direction Y. As can be seen from FIG. 4A, the plurality of first grooves 205 are formed by etching the substrate exposed by the plurality of first trench isolation structures 204, and therefore, the plurality of first grooves 205 and the corresponding plurality of first trench isolation structures 204 communicate with each other. In some embodiments, the plurality of first grooves 205 and the first trench isolation structures 204 may be formed in the same step; that is, while patterning the stack structure 200 to form the initial laminated structure 300, the substrate 201 is also patterned to form the plurality of first grooves 205 positioned in the substrate 201, which is not specifically limited in the embodiments of the present disclosure.

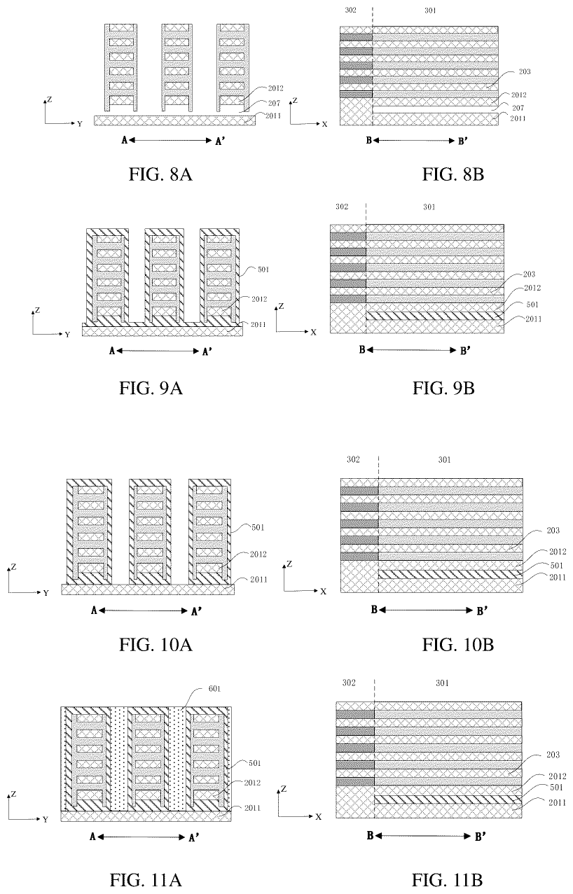

In step S03, a first dielectric layer is formed on the side walls of the plurality of first grooves; the substrate is etched along the bottoms of the plurality of first grooves to form a second groove positioned inside the substrate, such that along the second direction, two of the plurality of first grooves adjacent to each other communicate with each other through the second groove, and a second dielectric layer is filled within the second groove. Specifically, the following steps are included. As shown in FIGS. 5A and 5B, the plurality of first portions 301 in the initial laminated structure 300 are selectively etched through the first trench isolation structures 204 to remove the first semiconductor layers 202 in the plurality of first portions 301. In some embodiments, the first semiconductor layers 202 may be removed by a wet etching process, and the first semiconductor layers 202 on the first region I are removed based on an etching selectivity between the first semiconductor layers 202 and the second semiconductor layers 203 (e.g., greater than 10:1), while the second semiconductor layers 203 are substantially not etched or are etched by a very small amount, so as to form a plurality of first gaps 206 between the second semiconductor layers 203, where the plurality of first gaps 206 and the first trench isolation structures 204 communicate with each other. As shown in FIGS. 6A and 6B, the first dielectric layer 401 is deposited by chemical vapor deposition (CVD), physical vapor deposition (PVD), atomic layer deposition (ALD), or other processes, and the first dielectric layer 401 fills the plurality of first gaps 206, the side walls of the first trench isolation structures 204, and the side walls and bottoms of the plurality of first grooves 205. In some embodiments, after the first dielectric layer 401 is formed by deposition, the first dielectric layer at the top may be removed by a chemical mechanical polishing (CMP) process, such that the top of the polished first dielectric layer 401 is flush with the top surface of the second semiconductor layer 203 or the mask layer positioned at the uppermost layer. In some embodiments, the material of the deposited first dielectric layer includes one of silicon oxide (SiO2), silicon nitride (SiN), silicon oxynitride (SiON), and a low-k dielectric material, or a combination thereof, where the low-k dielectric material refers to a material with a dielectric constant less than 3. For example, the low-k dielectric material may be, but is not limited to, one or a combination of two or more of SiOH, SiOCH, fluorosilicate glass (FSG), borosilicate glass (BSG), phosphosilicate glass (PSG), and borophosphosilicate glass (BPSG). As shown in FIGS. 7A and 7B, the first dielectric layer 401 at the bottoms of the plurality of first grooves 205 is etched; the first dielectric layer at the bottoms is removed, while the first dielectric layer 401 positioned on the side walls of the plurality of first grooves 205 is remained. In some embodiments, the first dielectric layer 401 at the bottoms of the plurality of first grooves 205 may be etched by using a dry etching process; specifically, by using a plasma etching process, the first dielectric layer 401 is subjected to an anisotropic etching process to remove the first dielectric layer positioned at the bottoms of the plurality of first grooves 205, while the first dielectric layer 401 positioned on the side walls of the plurality of first grooves 205 and the first trench isolation structures 204 is not etched or is etched by a small amount. The surface of a portion of the substrate 201 is exposed by removing the first dielectric layer 401 at the bottoms of the plurality of first grooves 205. As shown in FIGS. 8A and 8B, by using the first dielectric layer 401 on the side walls of the plurality of first grooves 205 as an etching mask, the substrate 201 exposed at the bottoms of the plurality of first grooves 205 is etched to form the second groove 207 positioned inside the substrate 201, where the second groove 207 is positioned within the first region I of the substrate 201. As can be seen from FIGS. 7A, 8A, and 8B, the second groove 207 formed by etching is positioned inside the substrate 201; that is, the substrate 201 positioned in the first region I is isolated into a first substrate 2011 positioned below the second groove 207 and a second substrate 2012 positioned above the second groove 207 by the second groove 207. In some embodiments, the second groove 207 extends along the first direction X and the second direction Y and covers the entire first region I; that is, every two of the plurality of first grooves 205 adjacent to each other along the second direction Y communicate with each other through the second groove 207. In some embodiments, the substrate 201 is etched by a wet isotropic etching process to form the second groove 207. In the wet etching process, the etching selectivity for the substrate 201 and the first dielectric layer 401 is large (for example, greater than 10:1), such that the first dielectric layer 401 can be used as an etching barrier layer and is not etched or is etched by a small amount in the process of etching and removing a portion of the substrate 201. As shown in FIGS. 9A and 9B, the second dielectric layer 501 is deposited by chemical vapor deposition (CVD), physical vapor deposition (PVD), atomic layer deposition (ALD), or other processes, and the second dielectric layer 501 fills the second groove 207 completely and covers the side walls of the first dielectric layer 401. In some embodiments, the material of the deposited second dielectric layer includes one of silicon oxide (SiO2), silicon nitride (SiN), silicon oxynitride (SiON), and a low-k dielectric material, or a combination thereof. As shown in FIGS. 10A and 11A, the second dielectric layer 501 at the bottoms of the plurality of first grooves 205 is etched; the second dielectric layer at the bottoms is removed, while the second dielectric layer 501 positioned on the side walls of the plurality of first grooves 205 is remained. In some embodiments, the second dielectric layer 501 at the bottoms of the plurality of first grooves 205 may be etched by using a dry etching process; specifically, by using a plasma etching process, the second dielectric layer 501 is subjected to an anisotropic etching process to remove the second dielectric layer 501 positioned at the bottoms of the plurality of first grooves 205. As shown in FIG. 11A, the first sacrificial dielectric layer 601 is filled in the first trench isolation structures 204 and the plurality of first grooves 205, and may be formed by chemical vapor deposition, physical vapor deposition, or atomic layer deposition. Since the second dielectric layer 501 at the bottoms of the plurality of first grooves 205 is etched, the filled first sacrificial dielectric layer 601 is in direct contact with the first substrate 2011 in the substrate 201. In some embodiments, only a portion of the second dielectric layer 501 at the bottoms of the plurality of first grooves 205 may be removed, such that the first sacrificial dielectric layer 601 is not in direct contact with the first substrate 2011, but is in direct contact with a remaining portion of the second dielectric layer 501. In the embodiments of the present disclosure, whether the first sacrificial dielectric layer is in direct contact with the substrate is not specifically limited. In some embodiments, the first sacrificial dielectric layer 601 is made of polycrystalline silicon or a low-k dielectric material.

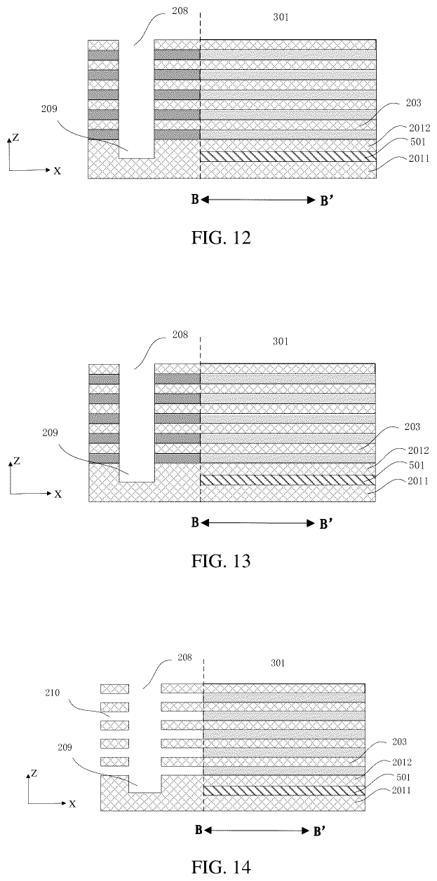

In step S04, a third groove is formed; the third groove is positioned in the second region of the substrate and extends along the second direction, and the third groove is positioned in the substrate. Specifically, the following steps are included. As shown in FIGS. 12 to 13, a mask layer (not shown) is formed above the second portion 302 of the initial laminated structure 300, and the second portion 302 is patterned to form a second trench isolation structure 208, where the patterning treatment includes dry etching, wet etching, or a combination of both, the second trench isolation structure 208 extends along the second direction Y, and the second trench isolation structure 208 exposes a portion of the surface of the substrate 201 positioned in the second region II. Through the exposed portion of the surface, the substrate 201 is subjected to dry or wet etching to form the third groove 209 positioned in the second region II of the substrate 201, and the third groove 209 extends along the second direction Y and extends along the third direction Z towards the inside of the substrate 201. As can be seen from FIGS. 12 to 13, the third groove 209 is formed by etching the substrate exposed by the second trench isolation structure 208, and therefore, the third groove 209 and the second trench isolation structure 208 communicate with each other. In some embodiments, the third groove 209 and the second trench isolation structure 208 may be formed in the same step; that is, while patterning the second portion 302, the substrate 201 is also patterned to form the third groove 209 positioned in the substrate 201, which is not specifically limited in the embodiments of the present disclosure.

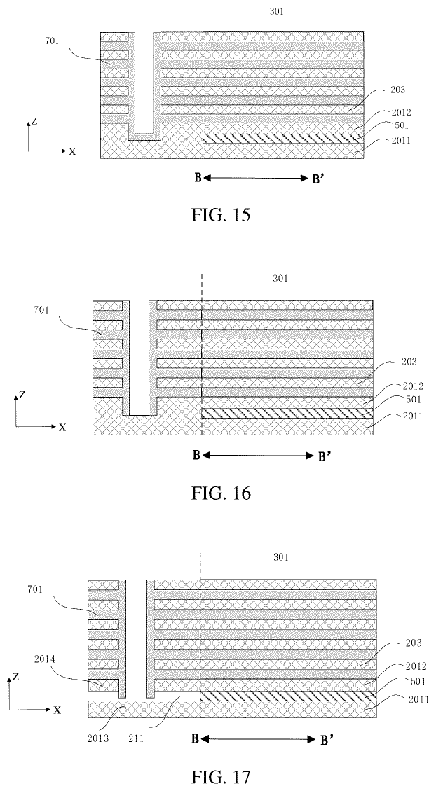

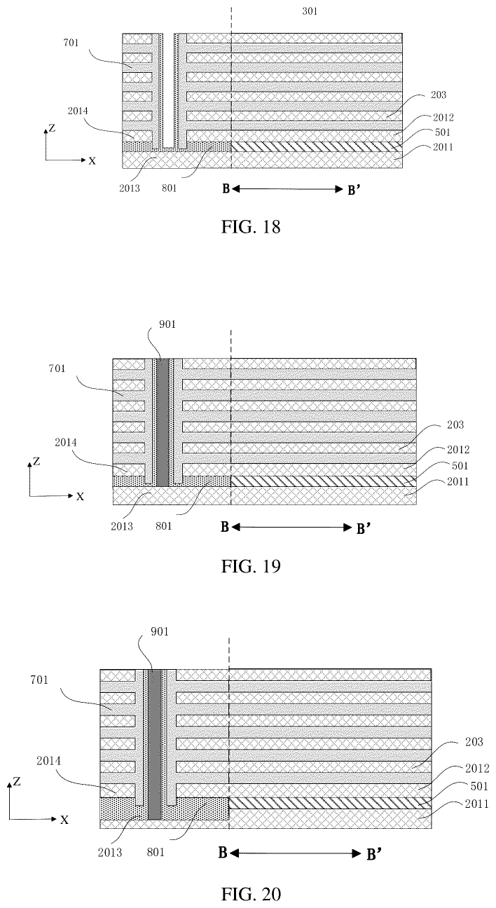

In step S05, a third dielectric layer is formed on the side walls of the third groove; the substrate is etched along the bottom of the third groove to form a fourth groove positioned inside the substrate, the fourth groove exposing the side surface of the second dielectric layer along the first direction; a fourth dielectric layer is filled within the fourth groove; the fourth dielectric layer positioned inside the substrate is interconnected to the second dielectric layer positioned inside the substrate. Specifically, the following steps are included. As shown in FIG. 14, the second portion 302 is selectively etched through the second trench isolation structure 208 to remove the first semiconductor layers 202 in the second portion 302. In some embodiments, the first semiconductor layers 202 may be removed by a wet etching process, and the first semiconductor layers 202 on the second region II are removed based on an etching selectivity between the first semiconductor layers 202 and the second semiconductor layers 203 (e.g., greater than 10:1), while the second semiconductor layers 203 are substantially not etched or are etched by a very small amount, so as to form a plurality of second gaps 210 between the second semiconductor layers 203, where the plurality of second gaps 210 and the second trench isolation structure 208 communicate with each other. As shown in FIG. 15, the third dielectric layer 701 is deposited by chemical vapor deposition, physical vapor deposition, atomic layer deposition, or other processes, and the third dielectric layer 701 fills the plurality of second gaps 210, the side walls of the second trench isolation structure 208, and the side walls and the bottom of the third groove 209. In some embodiments, after the third dielectric layer 701 is formed by deposition, the third dielectric layer 701 at the top may be removed by a chemical mechanical polishing process, such that the top of the polished third dielectric layer 701 is flush with the top surface of the second semiconductor layer 203 or the mask layer positioned at the uppermost layer. In some embodiments, the material of the deposited third dielectric layer includes one of silicon oxide (SiO2), silicon nitride (SiN), silicon oxynitride (SiON), and a low-k dielectric material, or a combination thereof. As shown in FIG. 16, the third dielectric layer 701 at the bottom of the third groove 209 is etched; the third dielectric layer at the bottom is removed, while the third dielectric layer 701 positioned on the side walls of the third groove 209 is remained. In some embodiments, the third dielectric layer 701 at the bottom of the third groove 209 may be etched by using a dry etching process; specifically, by using a plasma etching process, the third dielectric layer 701 is subjected to an anisotropic etching process to remove the third dielectric layer positioned at the bottom of the third groove 209, while the third dielectric layer 701 positioned on the side walls of the third groove 209 and the second trench isolation structure 208 is not etched or is etched by a small amount. The surface of a portion of the substrate 201 is exposed by removing the third dielectric layer 701 at the bottom of the third groove 209. As shown in FIG. 17, by using the third dielectric layer 701 on the side walls of the third groove 209 as an etching mask, the substrate 201 exposed at the bottom of the third groove 209 is etched to form the fourth groove 211 positioned inside the substrate 201, where the fourth groove 211 is positioned within the second region II of the substrate 201. As can be seen from FIG. 17, the fourth groove 211 formed by etching is positioned inside the substrate 201; that is, the substrate 201 positioned in the second region II is isolated into a third substrate 2013 positioned below the fourth groove 211 and a fourth substrate 2014 positioned above the fourth groove 211 by the third groove 209. In some embodiments, the fourth groove 211 extends along the first direction X and the second direction Y and covers the entire second region II. In some embodiments, the substrate 201 is etched by a wet isotropic etching process to form the fourth groove 211. In the wet etching process, the etching selectivity for the substrate 201 and the third dielectric layer 701 is large (for example, greater than 10:1), such that the third dielectric layer 701 can be used as an etching barrier layer and is not etched or is etched by a small amount in the process of etching and removing a portion of the substrate 201. As shown in FIG. 17, the fourth groove 211 positioned inside the substrate communicates with the third groove 209, and the fourth groove 211 exposes the side surface of the second dielectric layer 501 along the first direction X. As shown in FIG. 18, the fourth dielectric layer 801 is deposited by chemical vapor deposition, physical vapor deposition, atomic layer deposition, or other processes, and the fourth dielectric layer 801 fills the fourth groove 211 completely and covers the side walls of the third dielectric layer 701. In some embodiments, the material of the deposited fourth dielectric layer includes one of silicon oxide (SiO2), silicon nitride (SiN), silicon oxynitride (SiON), and a low-k dielectric material, or a combination thereof. As shown in FIG. 18, the filled fourth dielectric layer 801 is interconnected to the second dielectric layer 501 positioned inside the substrate of the first region I. In some embodiments, the material of the fourth dielectric layer 801 is the same as the material of the second dielectric layer 501, e.g., both being a silicon oxide material.

As shown in FIG. 19, the fourth dielectric layer 801 at the bottom the third groove 209 is etched; the fourth dielectric layer at the bottom is removed, while the fourth dielectric layer 801 positioned on the side walls of the third groove 209 is remained. In some embodiments, the fourth dielectric layer 801 at the bottom of the third groove 209 may be etched by using a dry etching process; specifically, by using a plasma etching process, the fourth dielectric layer 801 is subjected to an anisotropic etching process to remove the fourth dielectric layer 801 positioned at the bottom of the third groove 209. As shown in FIG. 19, the second sacrificial dielectric layer 901 is filled in the second trench isolation structure 208 and the third groove 209, and may be formed by chemical vapor deposition, physical vapor deposition, or atomic layer deposition. Since the fourth dielectric layer 801 at the bottom of the third groove 209 is etched, the filled second sacrificial dielectric layer 901 is in direct contact with the third substrate 2013 in the substrate 201. In some embodiments, only a portion of the fourth dielectric layer 801 at the bottom of the third groove 209 may be removed, such that the second sacrificial dielectric layer 901 is not in direct contact with the third substrate 2013, but is in direct contact with a remaining portion of the fourth dielectric layer 801. In the embodiments of the present disclosure, whether the second sacrificial dielectric layer is in direct contact with the substrate is not specifically limited. In some embodiments, the second sacrificial dielectric layer 901 is made of polycrystalline silicon or a low-k dielectric material.

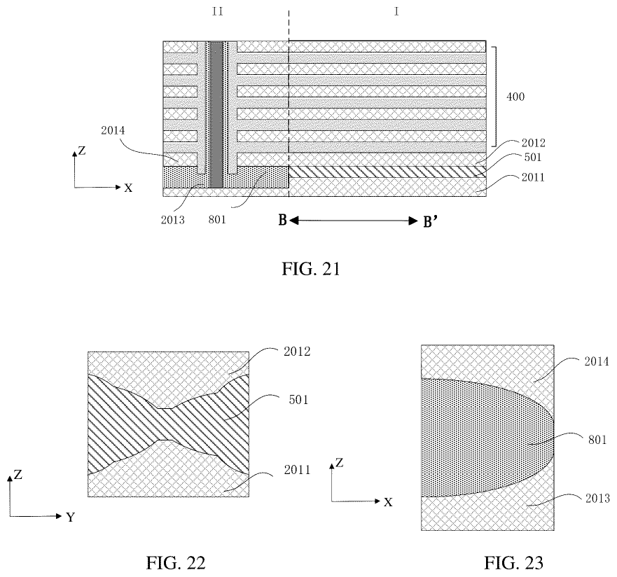

In some embodiments, the first substrate 2011 is interconnected to the third substrate 2013, and the second substrate 2012 is interconnected to the fourth substrate 2014. As shown in FIG. 19, the first substrate 2011 and the third substrate 2013 are of the same thickness. It can be appreciated by those skilled in the art that a wet isotropic etching process is used in the process of etching the substrate to form the second groove 207 and the fourth groove 211, such that the upper surfaces of the formed first substrate 2011 and third substrate 2013 or the lower surfaces of the formed second substrate 2012 and fourth substrate are not flat surfaces, namely irregular surfaces with arc or curved shapes. As shown in FIGS. 21 to 22, along the second direction Y, the interface between the second dielectric layer 501 and the first substrate 2011 and/or the second substrate 2012 is of a curved shape, and along the first direction, the interface between the fourth dielectric layer 801 and the third substrate 2013 and/or the fourth substrate 2014 is of a curved shape.

In some embodiments, in order to expose the overall side surface of the second dielectric layer 501 through the fourth groove 211, the etching time for etching the substrate in the second region to form the fourth groove 211 is longer than the etching time for etching the substrate in the first region to form the second groove 207, such that the depth of the fourth groove 211 formed by etching into the substrate is greater than the depth of the second groove 207 into the substrate. As shown in FIG. 20, finally, the thickness of the fourth dielectric layer 801 filled in the fourth groove is greater than the thickness of the second dielectric layer 501 filled in the second groove. In some embodiments, the contact surfaces of the fourth dielectric layer 801 and the second dielectric layer 501 positioned in the fourth groove 211 and the second groove 207 with the substrate (including the first substrate 2011, the second substrate 2012, the third substrate 2013, and the fourth substrate 2014) are irregular surfaces with arc or curved shapes; at this point, the thickness of the fourth dielectric layer 801 filled in the fourth groove is greater than the thickness of the second dielectric layer 501 filled in the second groove, where the thickness refers to an average thickness.

In another aspect of the present disclosure, a semiconductor structure is disclosed, which is formed by the above method for manufacturing a semiconductor structure. As shown in FIGS. 21 to 23, the semiconductor structure includes: a substrate 201; a stack device layer 400 positioned above the substrate 201, where the substrate 201 includes a first substrate 2011 and a second substrate 2012 positioned in a first region I and a third substrate 2013 and a fourth substrate 2014 positioned in a second region II; and a second dielectric layer 501 positioned between the first substrate 2011 and the second substrate 2012 and a fourth dielectric layer 801 positioned between the third substrate 2013 and the fourth substrate 2014 along a third direction Z, where the second dielectric layer 501 is interconnected to the fourth dielectric layer 801, the first substrate 2011 is interconnected to the third substrate 2013, and the second substrate 2012 is interconnected to the fourth substrate 2014. The thickness of the fourth dielectric layer 801 is greater than the thickness of the second dielectric layer 501.

In some embodiments, as shown in FIG. 22, along a second direction Y, the interface between the second dielectric layer 501 and the first substrate 2011 and/or the second substrate 2012 is of a curved shape. In some embodiments, as shown in FIG. 23, along the first direction, the interface between the fourth dielectric layer 801 and the third substrate 2013 and/or the fourth substrate 2014 is of a curved shape.

In some embodiments, the stack device layer 400 includes a plurality of transistor structures (not shown) and/or a plurality of capacitor structures (not shown) laminated along the third direction Z, and the transistor structure of each layer is electrically connected to the corresponding capacitor structure to form a memory cell structure.

In summary, according to the method for manufacturing a semiconductor structure and the semiconductor structure thereof provided in the embodiments of the present disclosure, the epitaxial stack structure is formed on the substrate, the lattice consistency of the epitaxial structure is improved, and the generation of dislocations or defects is reduced; the stack structure is etched to form the first trench isolation structures and the second trench isolation structure, which expose portions of the surface of the substrate; the substrate is etched through the first trench isolation structures and the second trench isolation structure to form the plurality of first grooves and the third groove deep into the substrate; the inside of the substrate is laterally etched through the plurality of first grooves and the third groove to form the second groove and the fourth groove inside the substrate; the insulating layers are filled inside the second groove and the fourth groove, such that the insulating layers prevent the substrate at the bottom from being etched, thereby playing a role of an etching stop layer, and at the same time, due to the isolation effect of the insulating layers, the generation of the leakage current can be effectively avoided. In addition, the upper part of the substrate and the stack structure are always maintained as an integral structure, such that the stripping of the stack structure from the substrate can be effectively prevented, the stability of the stack device structure is improved, and the electrical performance of the stack device structure is improved.

The various semiconductor structures shown in the specific embodiments can be used for an electronic apparatus having a memory function. The electronic apparatus may be a terminal apparatus, e.g., a mobile phone, a tablet computer, a smart bracelet, a personal computer (PC), a server, a workstation, or the like. The memory function in the electronic apparatus can be implemented by using the following memories: a dynamic random access memory (DRAM), a ferroelectric random access memory (FRAM), a phase change memory (PCM), a magnetic random access memory (MRAM), or a resistive random access memory (RRAM).

The above description illustrates only the specific embodiments of the present disclosure, but the protection scope of the present disclosure is not limited thereto; changes or substitutions that any one skilled in the art can easily think of within the technical scope disclosed by the present disclosure shall all fall within the protection scope of the present disclosure. Therefore, the protection scope of the present disclosure shall be defined by the protection scope of the claims.

1. A method for manufacturing a semiconductor structure, comprising:
providing a substrate, the substrate comprising a first region and a second region distributed along a first direction, and a stack structure being formed on the substrate;
forming a plurality of first grooves, the plurality of first grooves being positioned in the first region of the substrate and being positioned in the substrate, the plurality of first grooves extending along the first direction, the plurality of first grooves being spaced apart along a second direction, and a plane determined by the first direction and the second direction being parallel to a surface of the substrate;
forming a first dielectric layer on side walls of the plurality of first grooves;
etching the substrate along bottoms of the plurality of first grooves to form a second groove positioned inside the substrate, such that along the second direction, two of the plurality of first grooves adjacent to each other communicate with each other through the second groove; and
filling a second dielectric layer within the second groove.

2. The method for manufacturing a semiconductor structure according to claim 1, further comprising:
forming a third groove, the third groove being positioned in the second region of the substrate and extending along the second direction, and the third groove being positioned in the substrate;
forming a third dielectric layer on side walls of the third groove;
etching the substrate along a bottom of the third groove to form a fourth groove positioned inside the substrate, the fourth groove exposing a side surface of the second dielectric layer along the first direction;
filling a fourth dielectric layer within the fourth groove; and
interconnecting the fourth dielectric layer positioned inside the substrate to the second dielectric layer positioned inside the substrate.

3. The method for manufacturing a semiconductor structure according to claim 2, further comprising: before forming the plurality of first grooves, patterning the stack structure to form an initial laminated structure comprising a plurality of first portions positioned in the first region and a second portion positioned in the second region, wherein the plurality of first portions extend along the first direction and the second portion extends along the second direction;
the plurality of first portions are spaced apart along the second direction, and a first trench isolation structure is formed between two of the plurality of first portions adjacent to each other;
the substrate at bottoms of the first trench isolation structures is etched to form the plurality of first grooves; and
the plurality of first grooves communicate with the first trench isolation structures.

4. The method for manufacturing a semiconductor structure according to claim 3, further comprising: before forming the third groove, patterning the second portion of the second region to form a second trench isolation structure, wherein the second trench isolation structure extends along the second direction, and the substrate at a bottom of the second trench isolation structure is etched to form the third groove; and
the third groove communicates with the second trench isolation structure.

5. The method for manufacturing a semiconductor structure according to claim 4, wherein the second groove isolates the substrate positioned in the first region into a first substrate below the second groove and a second substrate above the second groove, the fourth groove isolates the substrate positioned in the second region into a third substrate below the fourth groove and a fourth substrate above the fourth groove, the first substrate is interconnected to the third substrate, and the second substrate is interconnected to the fourth substrate.

6. The method for manufacturing a semiconductor structure according to claim 5, further comprising: filling a first sacrificial dielectric layer within the first trench isolation structures, and filling a second sacrificial dielectric layer within the second trench isolation structure, the first sacrificial dielectric layer and/or the second sacrificial dielectric layer being made of polycrystalline silicon or a low-k dielectric material.

7. The method for manufacturing a semiconductor structure according to claim 6, wherein the first sacrificial dielectric layer and/or the second sacrificial dielectric layer are/is in contact with the substrate, or the second dielectric layer or the fourth dielectric layer is provided between the first sacrificial dielectric layer and/or the second sacrificial dielectric layer and the substrate.

8. The method for manufacturing a semiconductor structure according to claim 1, wherein the stack structure comprises first semiconductor layers and second semiconductor layers stacked sequentially, the first semiconductor layers are made of silicon germanium, and the second semiconductor layers are made of silicon.

9. The method for manufacturing a semiconductor structure according to claim 2, wherein the first dielectric layer, the second dielectric layer, the third dielectric layer, or the fourth dielectric layer is made of one or more of silicon oxide, silicon nitride, silicon oxynitride, and a low-k dielectric material.

10. The method for manufacturing a semiconductor structure according to claim 2, wherein along a third direction, a depth of the fourth groove is greater than or equal to a depth of the second groove, and the third direction intersects with the plane determined by the first direction and the second direction.

11. The method for manufacturing a semiconductor structure according to claim 10, wherein along the third direction, a thickness of the fourth dielectric layer is greater than a thickness of the second dielectric layer.

12. The method for manufacturing a semiconductor structure according to claim 7, wherein along the first direction, an interface between the fourth dielectric layer and the third substrate and/or the fourth substrate is in a shape of a curved surface.

13. The method for manufacturing a semiconductor structure according to claim 7, wherein along the second direction, an interface between the second dielectric layer and the first substrate and/or the second substrate is in a shape of a curved surface, and the plane determined by the first direction and the second direction is parallel to the surface of the substrate.

14. A semiconductor structure, comprising:
a substrate, comprising a first region and a second region distributed along a first direction;
a stack device layer, positioned on an upper surface of the substrate,
wherein the substrate comprises a first substrate and a second substrate positioned in the first region, and a third substrate and a fourth substrate positioned in the second region; the first substrate and the second substrate are spaced apart along a third direction, and the third substrate and the fourth substrate are spaced apart along the third direction; and the first direction is parallel to a surface of the substrate, and the third direction intersects with the surface of the substrate;
a second dielectric layer, positioned between the first substrate and the second substrate; and
a fourth dielectric layer, positioned between the third substrate and the fourth substrate,
wherein the second dielectric layer is interconnected to the fourth dielectric layer; and
along the third direction, a thickness of the fourth dielectric layer is greater than a thickness of the second dielectric layer.

15. The semiconductor structure according to claim 14, wherein along the first direction, an interface between the fourth dielectric layer and the third substrate and/or the fourth substrate is in a shape of a curved surface.

16. The semiconductor structure according to claim 14, wherein along a second direction, an interface between the second dielectric layer and the first substrate and/or the second substrate is in a shape of a curved surface, and a plane determined by the first direction and the second direction is parallel to the surface of the substrate.

17. The semiconductor structure according to claim 15, wherein the stack device layer comprises a plurality of transistor structures and/or a plurality of capacitor structures laminated along the third direction.

18. The semiconductor structure according to claim 14, wherein the second dielectric layer or the fourth dielectric layer is made of one or more of silicon oxide, silicon nitride, silicon oxynitride, and a low-k dielectric material.
